(19) United States
(12) Patent Application Publication
(10) Pub. No.: US 2018/0047315 A1
(43) Pub. Date: Feb. 15, 2018

(54) CHIP ON FILM, FLEXIBLE DISPLAY PANEL AND DISPLAY DEVICE

(71) Applicant: BOE TECHNOLOGY GROUP CO., LTD., Beijing (CN)

(72) Inventors: Hong LI, Beijing (CN); Liqiang CHEN, Beijing (CN)

(73) Assignee: BOE TECHNOLOGY GROUP CO., LTD., Beijing (CN)

(21) Appl. No.: 15/540,109

(22) PCT Filed: Jun. 15, 2016
(86) PCT No.: PCT/CN2016/085832

§ 371 Date: Jun. 27, 2017

(30) Foreign Application Priority Data
Feb. 4, 2016 (CN) 201610080918.0

(51) Int. Cl. G09F 9/30; H01L 27/12; H01L 23/00; G09G 3/20; H01L 23/488; H01L 23/528; H01L 21/77

(52) U.S. Cl. CPC G09F 9/301; H01L 23/528; H01L 27/12; H01L 21/77; G09G 3/20; H01L 23/488; H01L 24/01; H01L 2224/06

(57) ABSTRACT

A chip on film, including a base material provided with at least one row of output pads, wherein along an arranging direction of the output pads, an area where each row of output pads is located includes a first region, a second region and a third region, the second region is in the middle of the area where the row of output pads is located; the shape of each output pad located in the second region is different from the shape of each output pad located in the first region and the third region, and a maximum length spanned by each output pad located in the second region in the arranging direction is smaller than a minimum value among maximum lengths spanned by each output pad located in the first region and the third region in the arranging direction. A flexible display panel and a display device are further disclosed.

### TECHNICAL FIELD

Embodiments of the present disclosure relate to a chip on film, a flexible display panel and a display device.

### BACKGROUND

With the rapid development of display technology, flexible display panels have been paid attention by many users due to advantages of small size, light weight, resistant to drop and fall, bendable, energy saving and the like, and have become the focus of recent research.

A conventional manufacturing processes of a flexible display panel typically comprises the steps of firstly coating a polyimide (PI) film or a polyethylene terephthalate (PET) film on a rigid glass; and then performing evaporation on the PI film or the PET film acting as a flexible base so as to form a plurality of flexible display panels; and next, peeling off the plurality of flexible display panels thus formed from the rigid glass; and finally, cutting into a plurality of separate flexible display panels.

The evaporation process and the peeling process in the above processes both would cause the flexible display panel to expand. And, in a bonding area of the flexible display panel, expansion amount in the intermediate region is smaller than expansion amounts in the regions on both sides. Thus, when Chips On Film (COF) are bonded to the flexible display panel, there will be a problem that output pads of the COF and input pads in the bonding area of the flexible display panel are misaligned, resulting in poor bonding between the COF and the flexible display panel.

### SUMMARY

At least one embodiments of the present disclosure provides a chip on film, comprising a base material provided with at least one row of output pads, wherein: along an arranging direction of the output pads, an area where each row of output pads is located comprises a first region, a second region and a third region, the second region is in the middle of the area where the row of output pads is located; the shape of each output pad located in the second region is different from the shape of each output pad located in the first region and the third region, and a maximum length spanned by each output pad located in the second region in the arranging direction is smaller than a minimum value among maximum lengths spanned by each output pad located in the first region and the third region in the arranging direction.

At least one embodiment of the present disclosure provides a flexible display panel, comprising at least one row of input pads positioned in a bonding area of the flexible display panel; wherein, along an arranging direction of the input pads, the area where each row of input pads is located is divided into a first region, a second region and a third region, the second region is located in the middle of the area where the row of input pads is located; the shape of each input pad located in the second region is different from the shape of each input pad located in the first region and the third region, and the maximum length spanned by each input pad located in the second region in the arranging direction is smaller than the minimum value among the maximum lengths spanned by each input pad located in the first region and the third region in the arranging direction.

At least one embodiment of the present disclosure provides a display device comprising at least one of the chip on film mentioned and the flexible display panel mentioned above.

In the chip on film, the flexible display panel and the display device, since the expansion amount of the intermediate region in the bonding area of the flexible display panel is less than the expansion amount of the regions on both sides, the spacing between adjacent input pads in the intermediate region would be less than the spacing between adjacent input pads in the regions on both sides. Therefore, in the present disclosure, by making the input pads in each row of output pads in the bonding area of the chip on film which are located in different regions have different shapes, the input pads located in the intermediate region are shaped to occupy a relatively small space and the input pads in the regions on both sides are shaped to occupy a relatively large space, the chip on film can be adapted for deformations at different positions in the bonding area of the flexible display panel, thereby increasing the contact area between the input pads in the bonding area of the flexible display panel and the output pads of the chip on film, avoiding the misalignment between the output pads of the chip on film and the input pads in the bonding area of the flexible display panel, and improving the bonding yield of the chip on film and the flexible display panel.

### BRIEF DESCRIPTION OF THE DRAWINGS

In order to clearly illustrate the technical solutions of the embodiments of the disclosure, the drawings of the embodiments will be briefly described in the following; it is obvious that the drawings described below are only related to some embodiments of the disclosure and thus are not limitative of the disclosure.

FIG. 1 to FIG. 3 are illustrative structural views of the flexible display panel according to a first embodiment of the present disclosure respectively;

FIG. 4a to FIG. 4f are illustrative views of the shape of an input pad on the flexible display panel according to the embodiments of the present disclosure respectively;

FIG. 5 is an illustrative structural view of the flexible display panel according to a second embodiment of the present disclosure respectively; and

FIG. 6 to FIG. 8 are illustrative structural views of the chip on film according to the embodiments of the present disclosure respectively.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

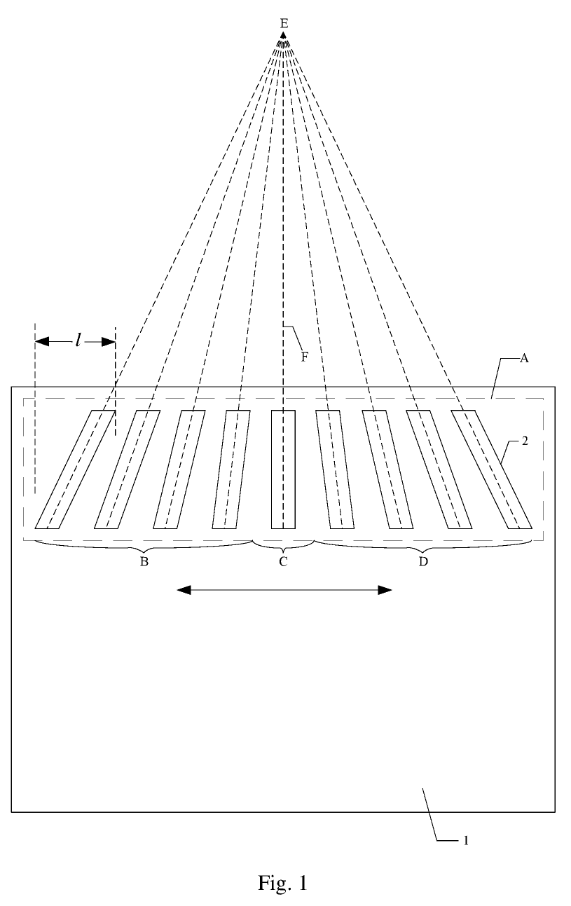

As illustrated in FIG. 1 to FIG. 3, a flexible display panel according to an embodiment of the present disclosure comprises at least one row of input pads 2 positioned in a bonding area A of the flexible display panel 1 (one row of input pads 2 is shown in FIG. 1 to FIG. 3).

Along the arranging direction of the input pads 2 (the arrow direction as illustrated in FIG. 1 to FIG. 3), the area where each row of input pads 2 is located is divided into a first region B, a second region C and a third region D. The second region C is located in the middle of the area where the row of input pads 2 is located. The shapes of the respective input pads 2 located in the second region C are different from the shape of the respective input pads 2 located in the first region B and the third region D, and the maximum length spanned by the respective input pads 2 located in the second region C in the arranging direction is smaller than the minimum value among the maximum lengths spanned by the respective input pads 2 located in the first region B and the third region D in the arranging direction (taking the input pads 2 located in the first region B as an example, the maximum length spanned in the arranging direction is indicated by l as illustrated in FIG. 1 to FIG. 3).

In the bonding area of the flexible display panel, if the spacing between adjacent input pads in the intermediate region is equal to the spacing between adjacent input pads in the regions on both sides, then during the bonding process, since in the bonding area of the flexible display panel, expansion amount of the intermediate region is less than expansion amount of the regions on both sides, and after bonding, the spacing between adjacent input pads in the intermediate region is less than the spacing between adjacent input pads in the regions on both sides. Therefore, in the present disclosure, by making the input pads in each row of input pads in the bonding area of the flexible display panel which are located in different regions have different shapes, so that the input pads located in the intermediate region are shaped to occupy a relatively small space and the input pads in the regions on both sides are shaped to occupy a relatively large space, the contact area between the input pads in the bonding area of the flexible display panel and the output pads of the chip on film can be increased so that the misalignment between the input pads in the bonding area of the flexible display panel and the output pads of the chip on film can be avoided, thereby improving the bonding yield of the chip on film and the flexible display panel.

In one embodiment of the present disclosure, in order to make the input pads located in the intermediate region be shaped to occupy a relatively small space and the input pads in the regions on both sides be shaped to occupy a relatively large space, in the first region B and the third region D, the maximum length spanned by the input pads is gradually increased as they move away from the second region C.

It is to be noted that in the above-described flexible display panel according to the embodiment of the present disclosure, FIG. 1 to FIG. 3 are described by exemplifying that the area where each row of input pads 2 is located is divided into the first region B, the second region C, and the third region D in the order from left to right. Of course, the area where each row of input pads is located is divided into the first region, the second region, and the third region in the order from right to left. Alternatively, the area can be divided into the first region, the second region and the third region in any order, which is not restricted in the present disclosure.

It is to be noted that in the above-described flexible display panel according to the embodiment of the present disclosure, the shape of each input pad located in the first region can be set to be the same; or alternatively, the shape of each input pad in different regions of the first region can be set to be different, that is to say, the first region is divided into a plurality of sub-regions, the shapes of the respective input pads located in the same sub-region are identical, while the shapes of the respective input pads located in different sub-regions are different, which is not restricted in the present disclosure. Likewise, the shape of each input pad located in the second region can be set to be the same; or alternatively, the shape of each input pad in different regions of the second region can be set to be different, that is to say, the second region is divided into a plurality of sub-regions, the shapes of the respective input pads located in the same sub-region are identical, while the shapes of the respective input pads located in different sub-regions are different, which is not restricted in the present disclosure. Likewise, the shape of each input pad located in the third region can be set to be the same; or alternatively, the shape of each input pad in different regions of the third region can be set to be different, that is to say, the third region is divided into a plurality of sub-regions, the shapes of the respective input pads located in the same sub-region are identical, while the shapes of the respective input pads located in different sub-regions are different, which is not restricted in the present disclosure.

Hereinafter, the embodiments of the above-described flexible display panel according to the embodiments of the present disclosure will be described in detail by way of three examples.

Example one: the area where each row of input pads is located is divided into three regions, i.e., a first region, a second region and a third region.

In the above-described flexible display panel according to one embodiment of the present disclosure, the second region is in the middle of the area where a row of input pads is located. The first region and the third region are respectively on both sides of the second region. Since the expansion amount of the intermediate region in the bonding area of the flexible display panel is less than the expansion amount of the regions on both sides, the spacing between adjacent input pads in the intermediate region is less than the spacing between the adjacent input pads in the regions on both sides. Therefore, to increase the contact area between the input pads in the bonding area of the flexible display panel and the output pads of the chip on film and avoid the misalignment between the output pads of the chip on film and the input pads in the bonding area of the flexible display panel, and improve the bonding yield of the chip on film and the flexible display panel, the shapes of the respective input pads in the second region are required to be set to occupy a relatively small space and the shapes of the respective input pads in the first region and the third region are required to be set to occupy a relatively large space. For example, as illustrated in FIG. 1, the shape of each input pad 2 located in the second region C can be set to be a rectangle, and the extending direction and the arranging direction of each input pad 2 located in the second region C are perpendicular to each other; the shape of each input pad 2 located in the first region B and the third region D can be set to be a parallelogram, the angle between the extending direction and the arranging direction of each input pad 2 located in the first region B and the third region D is greater than zero and less than 90°; the extending directions of at least part of the input pads 2 located in the first region B, the second region C and the third region D intersect at one point (FIG. 1 illustrates an example in which the extending directions of all the input pads 2 in one row intersect at Point E).

In one embodiment of the present disclosure, in the bonding area of the flexible display panel, the expansion amounts at two positions symmetrical with respect to the median line are identical and the input pads have an equal pitch, therefore in the above-described flexible display panel provided by the embodiment of the present invention, as illustrated in FIG. 1, the extending direction of each input pad 2 located in the first region B and the extending direction of each input pad 2 located in the third region D can be set to be symmetrical with respect to the median line F of the second region C which is perpendicular to the arranging direction. Thus, extending directions of two of the input pads 2 located in the first region B and the third region D which are at equal distances from the median line can be made to have an equal angle with respect to the median line and the two input pads can be made to occupy the same space. Such arrangement can further improve the compatibility of the chip on film with the flexible display panel, and enhance the bonding yield of the chip on film and the flexible display panel. For example, when the chip on film is bonded to the flexible display panel, a good contact between the output pads in the chip on film and the input pads in the bonding area of the flexible display panel can be achieved by moving the chip on film upward and downward, thereby ensuring the alignment yield of the chip on film and the flexible display panel.

In one embodiment of the present disclosure, taking an example that the number of the input pads included in each row of input pads is 1500-2500, in order to ensure that the adjacent input pads in the flexible display panel are not electrically connected with each other and guarantee the alignment yield of the output pads in the chip on film and the input pads in the bonding area of the flexible display panel, the angle between the extending direction and the arranging direction of each input pad can be controlled to be in the range of 70° to 80°. For example, the angle between the extending direction and the arranging direction of each input pad can be adjusted according to the number of the input pads included in each row of input pads by taking other factors in consideration, which is not restricted by the present disclosure.

Example two: the area where each row of input pads is located is divided into a first region, a second region and a third region, wherein the second region is divided into an even number of sub-regions. Taking an example that the second region is divided into two sub-regions, the area where each row of input pads is located is divided into four regions.

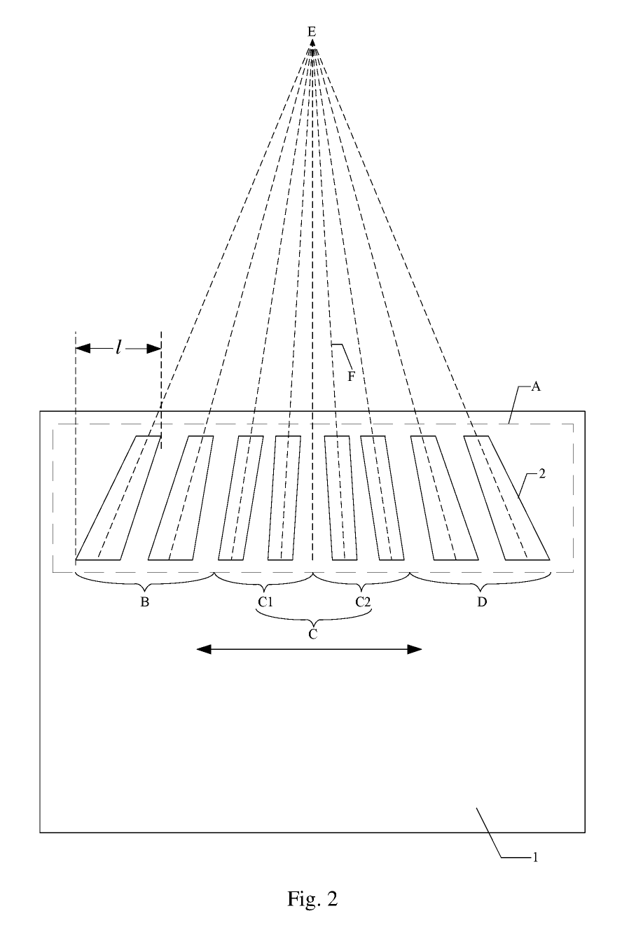

In the flexible display panel according to one embodiment of the present disclosure, the second region can be equally divided into M sub-regions, wherein M is even (i.e., M=2, 4, 6 . . . ). As illustrated in FIG. 2, which shows an example in which the second region C is equally divided into a first sub-region C1 and a second sub-region C2, the first sub-region C1 and the second sub-region C2 are in the middle of the area where a row of input pads 2 is located. The first region B and the third region D are respectively on both sides of the first sub-region C1 and the second sub-region C2. If the spacing between adjacent input pads in the intermediate region is equal to the spacing between adjacent input pads in the regions on both sides, since the expansion amount of the intermediate region in the bonding area of the flexible display panel is less than the expansion amount of the regions on both sides, the spacing between adjacent input pads in the intermediate region would become less than the spacing between the adjacent input pads in the regions on both sides. Therefore, to increase the contact area between the output pads of the chip on film and the input pads in the bonding area of the flexible display panel and avoid the misalignment between the output pads of the chip on film and the input pads in the bonding area of the flexible display panel, and improve the bonding yield of the chip on film and the flexible display panel, the shapes of the respective input pads 2 in the first sub-region C1 and the second sub-region C2 are required to be set to occupy a relatively small space and the shapes of the respective input pads 2 in the first region B and the third region D are required to be set to occupy a relatively large space. For example, as illustrated in FIG. 2, the shape of each input pad 2 located in first sub-region C1 and the second sub-region C2 can be set to be a parallelogram, and the angle between the extending direction and the arranging direction of each input pad 2 located in first sub-region C1 and the second sub-region C2 is greater than zero and less than 90°; the shape of each input pad 2 located in the first region B and the third region D is a trapezoid having two bottom sides parallel to the arranging direction, the angle between the extending direction and the arranging direction of each input pad 2 located in the first region B and the third region D is greater than zero and less than 90°; the extending directions of at least part of the input pads 2 located in the first region B, the first sub-region C1, the second sub-region C2 and the third region D intersect at one point (FIG. 2 illustrates an example in which the extending directions of all the input pads 2 in one row intersect at Point E); the length of the bottom side close to the intersection point E is less than the length of the bottom side away from the intersection point E.

In one embodiment of the present disclosure, in the bonding area of the flexible display panel, the expansion amounts at two positions symmetrical with respect to the median line are identical and the input pads have an equal pitch. Therefore, in the above-described flexible display panel according to the embodiment of the present disclosure, as illustrated in FIG. 2, the extending directions of the respective input pads 2 located in the second region C can be set to be symmetrical with respect to the median line F of the second region C which is perpendicular to the arranging direction, so that the extending directions of two of the input pads 2 located in the second region C, which are at equal distances from the median line, can be made to have an equal angle with respect to the median line and the two input pads can be made to occupy the same space. And, the extending direction of each input pad 2 located in the first region B and the extending direction of each input pad 2 located in the third region D can be set to be symmetrical with respect to the median line F of the second region C which is perpendicular to the arranging direction, so that the extending directions of two of the input pads 2 located in the first region B and the third region D which are at equal distances from the median line can be made to have an equal angle with respect to the median line and the two input pads can be made to occupy the same space. Such arrangement can further improve the compatibility of the chip on film with the flexible display panel, and enhance the bonding yield of the chip on film and the flexible display panel. For example, when the chip on film is bonded to the flexible display panel, a good contact between the output pads in the chip on film and the input pads in the bonding area of the flexible display panel can be achieved by moving the chip on film upward and downward, thereby ensuring the alignment yield of the chip on film and the flexible display panel.

In the above-described flexible display panel according to one embodiment of the present disclosure, taking an example that the number of the input pads included in each row of input pads is 1500-2500, in order to ensure that the adjacent input pads in the flexible display panel are not electrically connected with each other and guarantee an accurate alignment between the output pads in the chip on film and the input pads in the bonding area of the flexible display panel, the angle between the extending direction and the arranging direction of each input pad can be controlled to be in a range of 70° to 80°. For example, the angle between the extending direction and the arranging direction of each input pad can be adjusted according to the number of the input pads included in each row of input pads and in consideration of other factors, which is not restricted by the present disclosure.

Example three: the area where each row of input pads is located is divided into a first region, a second region and a third region, wherein the second region is divided into an odd number of sub-regions which is greater than 1. Taking an example that the second region is divided into three sub-regions, the area where each row of input pads is located is divided into five regions.

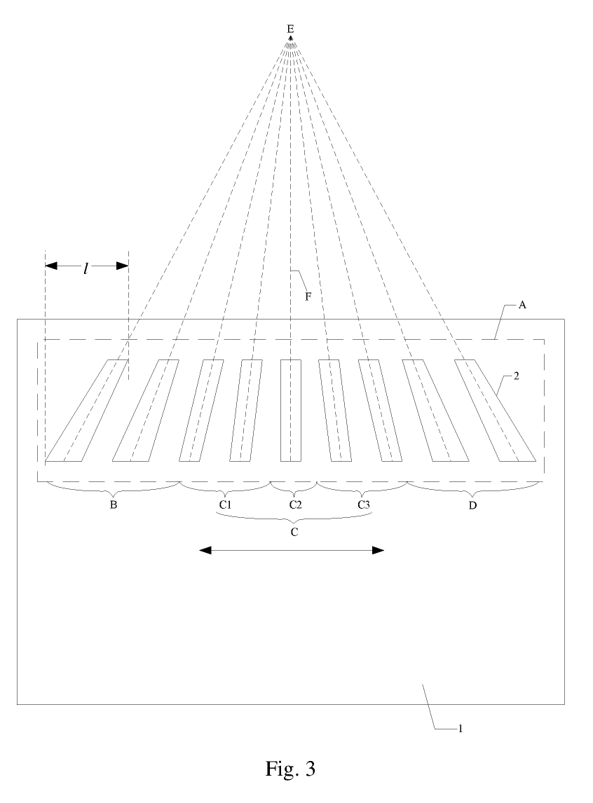

In the above-described flexible display panel according to one embodiment of the present disclosure, the second region can be equally divided into N sub-regions, wherein N is an odd number greater than 1 (i.e., N=3, 5, 7 . . . ). FIG. 3 illustrates an example that the second region C is equally divided into a first sub-region C1, a second sub-region C2 and a third sub-region C3. The second sub-region C2 is in the middle of the second region C. The second region C is in the middle of the area where a row of input pads 2 is located. That is to say, the second sub-region C2 is in the middle of the area where a row of input pads 2 is located. The first sub-region C1 and the third sub-region C3 are respectively on both sides of the second sub-region C2. The first region B and the third region D are respectively on a side of the first sub-region C1, the second sub-region C2 and the third sub-region C3. Since the expansion amount of the intermediate region in the bonding area of the flexible display panel is less than the expansion amount of the regions on both sides, the spacing between adjacent input pads in the intermediate region would become less than the spacing between the adjacent input pads in the regions on both sides. Therefore, to increase the contact area between the output pads of the chip on film and the input pads in the bonding area of the flexible display panel and avoid the misalignment between the output pads of the chip on film and the input pads in the bonding area of the flexible display panel, and improve the bonding yield of the chip on film and the flexible display panel, the shapes of the respective input pads 2 in the second sub-region C2 are required to be set to occupy a relatively small space, the shapes of the respective input pads 2 in the first sub-region C1 and the third sub-region C3 are required to be set to occupy a relatively large space, and the shapes of the respective input pads 2 in the first region B and the third region D are required to be set to occupy an even larger space. For example, as illustrated in FIG. 3, the shape of each input pad 2 located in the sub-region which is in the middle of the second region C, i.e., the second sub-region C2, can be set to be a rectangle, the extending direction and the arranging direction of each input pad 2 located in the second sub-region C2 are perpendicular to each other; the shape of each input pad 2 located in the sub-regions (i.e., the first sub-region C1 and the third sub-region C3) on both sides of the middle sub-region (i.e., the second sub-region C2) can be set to be a parallelogram, and the angle between the extending direction and the arranging direction of each input pad 2 located in first sub-region C1 and the third sub-region C3 is greater than zero and less than 90°; the shape of each input pad 2 located in the first region B and the third region D is a trapezoid having two bottom sides parallel to the arranging direction, the angle between the extending direction and the arranging direction of each input pad 2 located in the first region B and the third region D is greater than zero and less than 90°; the extending directions of at least part of the input pads 2 located in the first region B, the first sub-region C1, the second sub-region C2, the third sub-region C3 and the third region D intersect at one point (FIG. 3 illustrates an example in which the extending directions of all the input pads 2 in one row intersect at Point E); the length of the bottom side close to the intersection point E is less than the length of the bottom side away from the intersection point E.

In the bonding area of the flexible display panel, the expansion amounts at two positions symmetrical with respect to the median line are identical and the input pads have an equal pitch. Therefore, in the above-described flexible display panel according to one embodiment of the present disclosure, as illustrated in FIG. 3, the extending directions of the respective input pads 2 located in the sub-regions (i.e., the first sub-region C1 and the third sub-region C3) on both sides of the middle sub-region (i.e., the second sub-region C2) of the second region C can be set to be symmetrical with respect to the median line F of the second region C which is perpendicular to the arranging direction, so that the extending directions of two of the input pads 2 located in the first sub-region C1 and the third sub-region C3, which are at equal distances from the median line, can be made to have an equal angle with respect to the median line and the two input pads can be made to occupy the same space. And, the extending direction of each input pad 2 located in the first region B and the extending direction of each input pad 2 located in the third region D can be set to be symmetrical with respect to the median line F of the second region C which is perpendicular to the arranging direction, so that the extending directions of two of the input pads 2 located in the first region B and the third region D which are at equal distances from the median line can be made to have an equal angle with respect to the median line and the two input pads can be made to occupy the same space. Such arrangement can further improve the compatibility of the chip on film with the flexible display panel, and enhance the bonding yield of the chip on film and the flexible display panel. For example, when the chip on film is bonded to the flexible display panel, a good contact between the output pads in the chip on film and the input pads in the bonding area of the flexible display panel can be achieved by moving the chip on film upward and downward, thereby ensuring an accurate alignment between the chip on film and the flexible display panel.

In the above-described flexible display panel according to one embodiment of the present disclosure, taking an example that the number of the input pads included in each row of input pads is 1500-2500, in order to ensure that the adjacent input pads in the flexible display panel are not electrically connected with each other and guarantee an accurate alignment between the output pads in the chip on film and the input pads in the bonding area of the flexible display panel, the angle between the extending direction and the arranging direction of each input pad can be controlled to be in a range of 70° to 80°. For example, the angle between the extending direction and the arranging direction of each input pad can be adjusted according to the number of the input pads included in each row of input pads and in consideration of other factors, which is not restricted by the present disclosure.

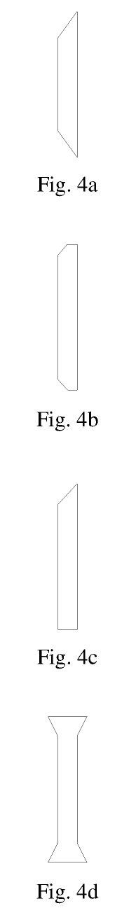

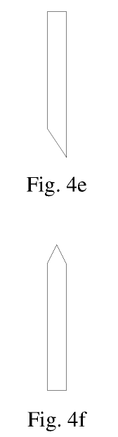

It is to be noted that in the above-described flexible display panel according to the embodiments of the present disclosure, it is not restricted that the area where each row of input pads is located is divided into three regions, four regions or five regions, and the area where each row of input pads is located can be divided into more regions, which is not restricted in the present disclosure. Moreover, the shapes of the input pads are not limited to rectangle, parallelogram and trapezoid, but can be other similar shapes such as the shapes as illustrated in FIG. 4a to FIG. 4f, which is not restricted in the present disclosure.

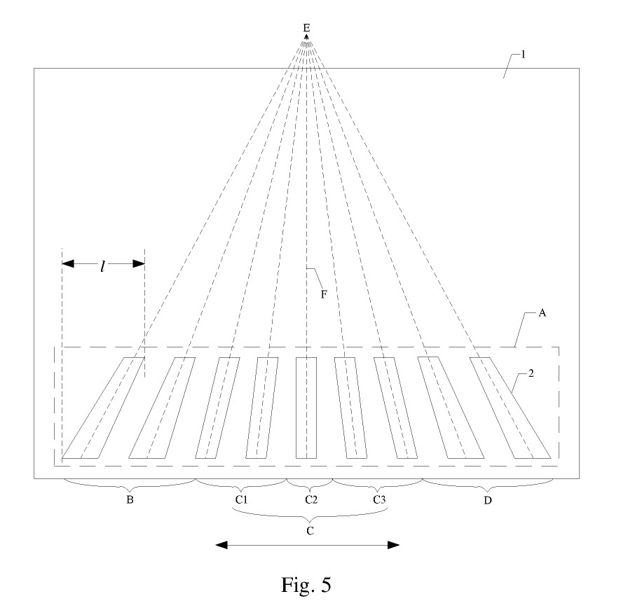

It is to be noted that in the above-described flexible display panel according to the embodiments of the present disclosure, FIG. 1 to FIG. 3 illustrate an example in which each row of input pads 2 inwardly converges, i.e., the intersection point E of the extending directions of the input pads 2 in each row is on a side away from the flexible display panel 1. Of course, each row of input pads can also be diffused outwardly as illustrated in FIG. 5, i.e., the intersection point E of the extending directions of the input pads 2 in each row is on a side close to the flexible display panel 1. It is not restricted by the present disclosure.

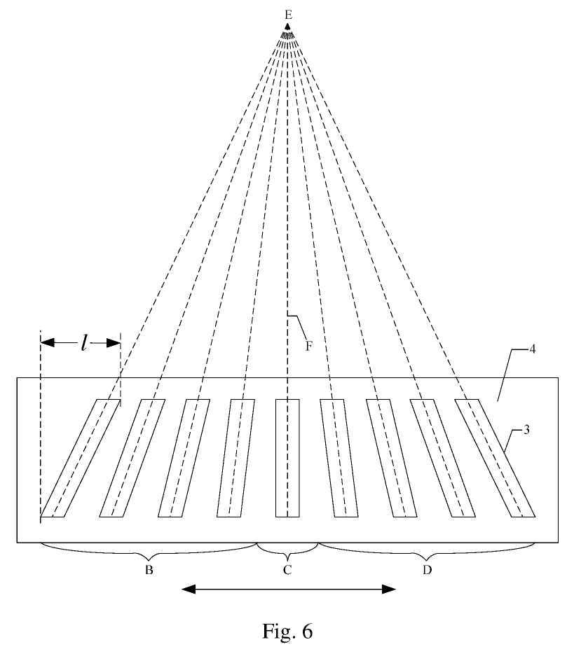

Based on the same inventive concept, embodiments of the present disclosure further provide a chip on film, as illustrated in FIG. 6 to FIG. 8, comprising a base material 4 on which at least one row of output pads 3 are provided (only one row of output pads 3 is shown in FIG. 6 to FIG. 8).

Along the arranging direction of the output pads 3 (the arrow direction as illustrated in FIG. 6 to FIG. 8), the area where each row of output pads 3 is located is divided into a first region B, a second region C and a third region D. The second region C is in the middle of the area where the row of output pads 3 is located. The shape of each output pad 3 located in the second region C is different from the shape of each output pad 3 located in the first region B and the third region D, and the maximum length spanned by each output pad 3 located in the second region C in the arranging direction is smaller than the minimum value among the maximum lengths spanned by each output pad 3 located in the first region B and the third region D in the arranging direction (taking the output pads 3 located in the first region B as an example, the maximum length spanned in the arranging direction is indicated by l as illustrated in FIG. 6 to FIG. 8).

In one embodiment of the present disclosure, in order to make the input pads located in the intermediate region be shaped to occupy a relatively small space and the input pads in the regions on both sides be shaped to occupy a relatively large space, in the first region B and the third region D, the maximum length spanned by the input pads is gradually increased as they move away from the second region C.

Since in the bonding area of the flexible display panel, the expansion amount of the intermediate region is less than the expansion amount of the regions on both sides, the spacing between adjacent input pads in the intermediate region would be less than the spacing between adjacent input pads in the regions on both sides. Therefore, by making the output pads in each row of output pads in the chip on film which are located in different regions have different shapes, so that the output pads located in the intermediate region are shaped to occupy a relatively small space and the output pads in the regions on both sides are shaped to occupy a relatively large space, the chip on film can be adapted for deformations at different positions in the bonding area of the flexible display panel and can be compatible with different expansion amounts at different positions in the bonding area of the flexible display panel, which increases the contact area between the output pads of the chip on film and the input pads in the bonding area of the flexible display panel and thus avoids the misalignment between the output pads of the chip on film and the input pads in the bonding area of the flexible display panel, thereby improving the bonding yield of the chip on film and the flexible display panel.

It is to be noted that in the above-described chip on film according to the embodiment of the present disclosure, FIG. 6 to FIG. 8 are described by exemplifying that the area where each row of output pads 3 is located is divided into the first region B, the second region C, and the third region D in the order from left to right. Of course, the area where each row of output pads is located can be divided into the first region, the second region, and the third region in the order from right to left, which is not restricted here.

It is to be noted that in the above-described chip on film according to the embodiment of the present disclosure, the shape of each output pad located in the first region can be set to be the same; or alternatively, the shape of each output pad in different regions of the first region can be set to be different, that is to say, the first region is divided into a plurality of sub-regions, the shapes of the respective output pads located in the same sub-region are identical, while the shapes of the respective output pads located in different sub-regions are different, which is not restricted in the present disclosure. Likewise, the shape of each output pad located in the second region can be set to be the same; or alternatively, the shape of each output pad in different regions of the second region can be set to be different, that is to say, the second region is divided into a plurality of sub-regions, the shapes of the respective output pads located in the same sub-region are identical, while the shapes of the respective output pads located in different sub-regions are different, which is not restricted in the present disclosure. Likewise, the shape of each output pad located in the third region can be set to be the same; or alternatively, the shape of each output pad in different regions of the third region can be set to be different, that is to say, the third region is divided into a plurality of sub-regions, the shapes of the respective output pads located in the same sub-region are identical, while the shapes of the respective output pads located in different sub-regions are different, which is not restricted in the present disclosure.

Hereinafter, the implementation of the chip on film according to the embodiments of the present disclosure will be described in detail by way of three examples.

Example four: the area where each row of output pads is located is divided into three regions, i.e., a first region, a second region and a third region.

In the chip on film according to one embodiment of the present disclosure, the second region is in the middle of the area where a row of output pads is located. The first region and the third region are respectively on both sides of the second region. Since the expansion amount of the intermediate region in the bonding area of the flexible display panel is less than the expansion amount of the regions on both sides, the spacing between adjacent input pads in the intermediate region would be less than the spacing between adjacent input pads in the regions on both sides. Therefore, to make the chip on film adapted for deformations at different positions in the bonding area of the flexible display panel and compatible with different expansion amounts at different positions in the bonding area of the flexible display panel, and to increase the contact area between the output pads of the chip on film and the input pads in the bonding area of the flexible display panel and to avoid the misalignment between the output pads of the chip on film and the input pads in the bonding area of the flexible display panel, and to improve the bonding yield of the chip on film and the flexible display panel, the shapes of the respective output pads in the second region are required to be set to occupy a relatively small space and the shapes of the respective output pads in the first region and the third region are required to be set to occupy a relatively large space. For example, as illustrated in FIG. 6, the shape of each output pad 3 located in the second region C can be set to be a rectangle, and the extending direction and the arranging direction of each output pad 3 located in the second region C are perpendicular to each other; the shape of each output pad 3 located in the first region B and the third region D can be set to be a parallelogram, the angle between the extending direction and the arranging direction of each output pad 3 located in the first region B and the third region D is greater than zero and less than 90°; the extending directions of at least part of the output pads 3 located in the first region B, the second region C and the third region D intersect at one point (FIG. 6 illustrates an example in which the extending directions of all the output pads 3 in one row intersect at Point E).

In one embodiment of the present disclosure, in the bonding area of the flexible display panel, the expansion amounts at two positions symmetrical with respect to the median line are identical and the input pads have an equal pitch, therefore in the chip on film according to the embodiment of the present invention, as illustrated in FIG. 6, the extending direction of each output pad 3 located in the first region B and the extending direction of each output pad 3 located in the third region D can be set to be symmetrical with respect to the median line F of the second region C which is perpendicular to the arranging direction. Thus, extending directions of two of the output pads 3 located in the first region B and the third region D which are at equal distances from the median line can be made to have an equal angle with respect to the median line and the two output pads can be made to occupy the same space. Such arrangement can further improve the compatibility of the chip on film with the flexible display panel, and enhance the bonding yield of the chip on film and the flexible display panel. For example, when the chip on film is bonded to the flexible display panel, a good contact between the output pads in the chip on film and the input pads in the bonding area of the flexible display panel can be achieved by moving the chip on film upward and downward, thereby ensuring the alignment yield of the chip on film and the flexible display panel.

In the above-described chip on film according to one embodiment of the present disclosure, taking an example that the number of the output pads included in each row of output pads is 1500-2500, in order to ensure that the adjacent output pads in the chip on film are not electrically connected with each other and guarantee the alignment yield of the output pads in the chip on film and the input pads in the bonding area of the flexible display panel, the angle between the extending direction and the arranging direction of each output pad can be controlled to be in a range of 70° to 80°. At the time of implementation, the angle between the extending direction and the arranging direction of each output pad can be adjusted according to the number of the output pads included in each row of output pads in the chip on film and in consideration of other factors, which is not restricted by the present disclosure.

Example five: the area where each row of output pads is located is divided into three regions, i.e., a first region, a second region and a third region, wherein the second region is divided into an even number of sub-regions. Taking an example that the second region is divided into two sub-regions, in which the area where each row of output pads is located is divided into four regions.

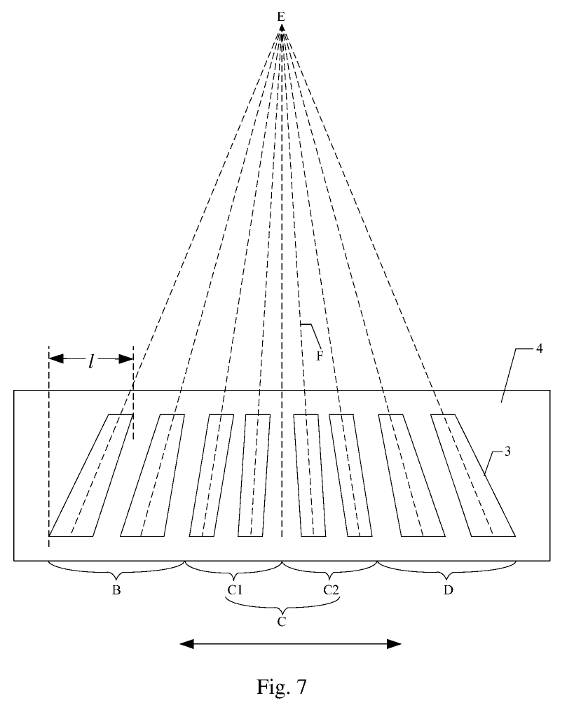

In the above-described chip on film according to one embodiment of the present disclosure, the second region can be equally divided into M sub-regions, wherein M is even (i.e., M=2, 4, 6 . . . ). FIG. 7 illustrates an example in which the second region C is equally divided into a first sub-region C1 and a second sub-region C2. The first sub-region C1 and the second sub-region C2 are in the middle of the area where a row of output pads 3 is located. The first region B and the third region D are respectively on both sides of the first sub-region C1 and the second sub-region C2. The expansion amount of the intermediate region in the bonding area of the flexible display panel is less than the expansion amount of the regions on both sides, the spacing between adjacent input pads in the intermediate region would become less than the spacing between the adjacent input pads in the regions on both sides. Therefore, to make the chip on film adapted for deformations at different positions in the bonding area of the flexible display panel and compatible with different expansion amounts at different positions in the bonding area of the flexible display panel, and to increase the contact area between the output pads of the chip on film and the input pads in the bonding area of the flexible display panel and to avoid the misalignment between the output pads of the chip on film and the input pads in the bonding area of the flexible display panel, and to improve the bonding yield of the chip on film and the flexible display panel, the shapes of the respective output pads 3 in the first sub-region C1 and the second sub-region C2 are required to be set to occupy a relatively small space and the shapes of the respective output pads 2 in the first region B and the third region D are required to be set to occupy a relatively large space. For example, as illustrated in FIG. 7, the shape of each output pad 3 located in first sub-region C1 and the second sub-region C2 is a parallelogram, and the angle between the extending direction and the arranging direction of each output pad 3 located in first sub-region C1 and the second sub-region C2 is greater than zero and less than 90°; the shape of each output pad 3 located in the first region B and the third region D is a trapezoid having two bottom sides parallel to the arranging direction, the angle between the extending direction and the arranging direction of each output pad 3 located in the first region B and the third region D is greater than zero and less than 90°; the extending directions of at least part of the output pads 3 located in the first region B, the first sub-region C1, the second sub-region C2 and the third region D intersect at one point (FIG. 7 illustrates an example in which the extending directions of all the output pads 3 in one row intersect at Point E); the length of the bottom side close to the intersection point E is less than the length of the bottom side away from the intersection point E.

In the bonding area of the flexible display panel, the expansion amounts at two positions symmetrical with respect to the median line are identical and the input pads have an equal pitch. Therefore, in the chip on film according to one embodiment of the present disclosure, for example, as illustrated in FIG. 7, the extending directions of the respective output pads 3 located in the second region C can be set to be symmetrical with respect to the median line F of the second region C which is perpendicular to the arranging direction, so that the extending directions of two of the output pads 3 located in the second region C, which are at equal distances from the median line, can be made to have an equal angle with respect to the median line and the two output pads can be made to occupy the same space. And, each output pad 3 located in the first region B and each output pad 3 located in the third region D can be set to be symmetrical with respect to the median line F of the second region C which is perpendicular to the arranging direction, so that the extending directions of two of the output pads 3 located in the first region B and the third region D which are at equal distances from the median line can be made to have an equal angle with respect to the median line and the two output pads can be made to occupy the same space. Such arrangement can further improve the compatibility of the chip on film with the flexible display panel, and enhance the bonding yield of the chip on film and the flexible display panel. When the chip on film is bonded to the flexible display panel, a good contact between the output pads in the chip on film and the input pads in the bonding area of the flexible display panel can be achieved by moving the chip on film upward and downward, thereby ensuring the alignment yield of the chip on film and the flexible display panel.

In the chip on film according to one embodiment of the present disclosure, taking an example that the number of the output pads included in each row of output pads is 1500-2500, in order to ensure that the adjacent output pads in the chip on film are not electrically connected with each other and ensure the alignment yield between the output pads in the chip on film and the input pads in the bonding area of the flexible display panel, the angle between the extending direction and the arranging direction of each output pad can be controlled to be in a range of 70° to 80°. For example, the angle between the extending direction and the arranging direction of each output pad can be adjusted according to the number of the output pads included in each row of output pads in the chip on film and in consideration of other factors, which is not restricted by the present disclosure.

Example six: the area where each row of output pads is located is divided into three regions, i.e., a first region, a second region and a third region, wherein the second region is divided into an odd number of sub-regions which is greater than 1. Taking an example that the second region is divided into three sub-regions, the area where each row of output pads is located is divided into five regions.

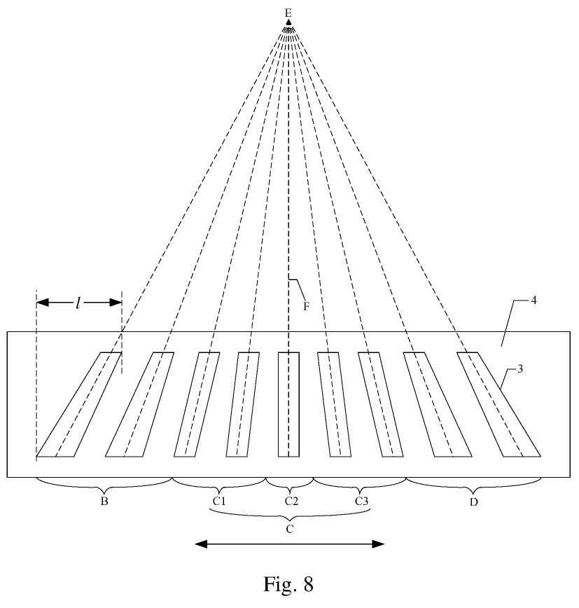

In the chip on film according to one embodiment of the present disclosure, the second region can be equally divided into N sub-regions, wherein N is an odd number greater than 1 (i.e., N=3, 5, 7 . . . ). FIG. 8 illustrates an example that the second region C is equally divided into a first sub-region C1, a second sub-region C2 and a third sub-region C3. The second sub-region C2 is in the middle of the second region C. The second region C is in the middle of the area where a row of output pads 3 is located. That is to say, the second sub-region C2 is in the middle of the area where a row of output pads 3 is located. The first sub-region C1 and the third sub-region C3 are respectively on both sides of the second sub-region C2. The first region B and the third region D are respectively on both sides of the first sub-region C1, the second sub-region C2 and the third sub-region C3. Since the expansion amount of the intermediate region in the bonding area of the flexible display panel is less than the expansion amount of the regions on both sides, the spacing between adjacent input pads in the intermediate region would become less than the spacing between the adjacent input pads in the regions on both sides. Therefore, to make the chip on film adapted for deformations at different positions in the bonding area of the flexible display panel and compatible with different expansion amounts at different positions in the bonding area of the flexible display panel, and to increase the contact area between the output pads of the chip on film and the input pads in the bonding area of the flexible display panel and to avoid the misalignment between the output pads of the chip on film and the input pads in the bonding area of the flexible display panel, and to improve the bonding yield of the chip on film and the flexible display panel, the shapes of the respective output pads 3 in the second sub-region C2 are required to be set to occupy a relatively small space, the shapes of the respective output pads 3 in the first sub-region C1 and the third sub-region C3 are required to be set to occupy a relatively large space, and the shapes of the respective output pads 3 in the first region B and the third region D are required to be set to occupy an even larger space. For example, as illustrated in FIG. 8, the shape of each output pad 3 located in the sub-region which is in the middle of the second region C, i.e., the second sub-region C2, is a rectangle, the extending direction and the arranging direction of each output pad 3 located in the second sub-region C2 are perpendicular to each other; the shape of each output pad 3 located in the sub-regions (i.e., the first sub-region C1 and the third sub-region C3) on both sides of the middle sub-region (i.e., the second sub-region C2) is a parallelogram, and the angle between the extending direction and the arranging direction of each output pad 3 located in first sub-region C1 and the third sub-region C3 is greater than zero and less than 90°; the shape of each output pad 3 located in the first region B and the third region D is a trapezoid having two bottom sides parallel to the arranging direction, the angle between the extending direction and the arranging direction of each output pad 3 located in the first region B and the third region D is greater than zero and less than 90°; the extending directions of at least part of the output pads 3 located in the first region B, the first sub-region C1, the second sub-region C2, the third sub-region C3 and the third region D intersect at one point (FIG. 8 illustrates an example in which the extending directions of all the output pads 3 in one row intersect at Point E); the length of the bottom side close to the intersection point E is less than the length of the bottom side away from the intersection point E.

In the bonding area of the flexible display panel, the expansion amounts at two positions symmetrical with respect to the median line are identical and the input pads have an equal pitch. Therefore, in the above-described chip on film according to one embodiment of the present disclosure, as illustrated in FIG. 8, the respective output pads 3 located in the sub-regions (i.e., the first sub-region C1 and the third sub-region C3) on both sides of the middle sub-region (i.e., the second sub-region C2) of the second region C can be set to be symmetrical with respect to the median line F of the second region C which is perpendicular to the arranging direction, so that the extending directions of two of the output pads 3 located in the first sub-region C1 and the third sub-region C3, which are at equal distances from the median line, can be made to have an equal angle with respect to the median line and the two output pads can be made to occupy the same space. And, the respective output pads 3 located in the first region B and the respective output pads 3 located in the third region D can be set to be symmetrical with respect to the median line F of the second region C which is perpendicular to the arranging direction, so that the extending directions of two of the output pads 3 located in the first region B and the third region D which are at equal distances from the median line can be made to have an equal angle with respect to the median line and the two output pads can be made to occupy the same space. Such arrangement can further improve the compatibility of the chip on film with the flexible display panel, and enhance the bonding yield of the chip on film and the flexible display panel. For example, when the chip on film is bonded to the flexible display panel, a good contact between the output pads in the chip on film and the input pads in the bonding area of the flexible display panel can be achieved by moving the chip on film upward and downward, thereby ensuring the alignment yield of the chip on film and the flexible display panel.

In the above-described chip on film according to one embodiment of the present disclosure, taking an example that the number of the output pads included in each row of output pads is 1500-2500, in order to ensure that the adjacent output pads in the chip on film are not electrically connected with each other and ensure the alignment yield of the output pads in the chip on film and the input pads in the bonding area of the flexible display panel, the angle between the extending direction and the arranging direction of each output pad can be controlled to be in a range of 70° to 80°. At the time of implementation, the angle between the extending direction and the arranging direction of each output pad can be adjusted according to the number of the output pads included in each row of output pads and in consideration of other factors, which is not restricted by the present disclosure.

It is to be noted that in the chip on film according to the embodiments of the present disclosure, it is not restricted that the area where each row of output pads is located is divided into three regions, four regions or five regions, and the area where each row of output pads is located can be divided into more regions, which is not restricted in the present disclosure. Moreover, the shapes of the output pads are not limited to rectangle, parallelogram and trapezoid, but can be other similar shapes such as the shapes as illustrated in FIG. 4a to FIG. 4f, which is not restricted in the present disclosure.

Based on the same inventive concept, at least one embodiment of the present disclosure further provides a display device comprising the chip on film according to the above-described embodiments of the present disclosure and/or the flexible display panel according to the above-described embodiments of the present disclosure. The display device can be any product or component having a display function such as a cell phone, a tablet computer, a television set, a monitor, a laptop, a digital photo frame, a navigator, or the like. The implementation of the display device can refer to the above-described embodiments of the chip on film and the flexible display panel, and details will be omitted to avoid repetition.

In the chip on film, the flexible display panel and the display device according to the embodiments of the present disclosure, in the bonding area of the flexible display panel, the expansion amount of the intermediate region is less than the expansion amount of the regions on both sides, the spacing between adjacent input pads in the intermediate region would be less than the spacing between adjacent input pads in the regions on both sides. Therefore, by making the output pads in the chip on film which are located in different regions have different shapes, so that the output pads located in the intermediate region are shaped to occupy a relatively small space and the output pads in the regions on both sides are shaped to occupy a relatively large space, the chip on film can be adapted for deformations at different positions in the bonding area of the flexible display panel, which increases the contact area between the chip on film and the bonding area of the flexible display panel and avoids the misalignment between the output pads of the chip on film and the input pads in the bonding area of the flexible display panel, thereby improving the bonding yield of the chip on film and the flexible display panel.

The foregoing are merely exemplary embodiments of the disclosure, but are not used to limit the protection scope of the disclosure. The protection scope of the disclosure shall be defined by the attached claims.

The present disclosure claims priority of Chinese Patent Application No. 201610080918.0 filed on Feb. 4, 2016, the disclosure of which is hereby entirely incorporated by reference as a part of the present disclosure.

1. A chip on film, comprising a base material provided with at least one row of output pads, wherein:
along an arranging direction of the output pads, an area where each row of output pads is located comprises a first region, a second region and a third region, the second region is in the middle of the area where the row of output pads is located; the shape of each output pad located in the second region is different from the shape of each output pad located in the first region and the third region, and a maximum length spanned by each output pad located in the second region in the arranging direction is smaller than a minimum value among maximum lengths spanned by each output pad located in the first region and the third region in the arranging direction.

2. The chip on film according to claim 1, wherein:
the shape of each output pad located in the second region is a rectangle, and the extending direction and the arranging direction of each output pad located in the second region are perpendicular to each other;
the shape of each output pad located in the first region and the third region is a parallelogram, and the angle between the extending direction and the arranging direction of each output pad located in the first region and the third region is greater than zero and less than 90°; the extending directions of at least part of the output pads located in the first region, the second region and the third region intersect at one point.

3. The chip on film according to claim 2, wherein the extending directions of the respective output pads located in the first region and the extending directions of the respective output pads located in the third region is symmetrical with respect to a median line of the second region which is perpendicular to the arranging direction.

4. The chip on film according to claim 1, wherein the second region is equally divided into M sub-regions, M is an even number;
the shape of each output pad located in each sub-region is a parallelogram; the angle between the extending direction and the arranging direction of each output pad located in each sub-region is greater than zero and less than 90°;
the shape of each output pad located in the first region and the third region is a trapezoid having two bottom sides parallel to the arranging direction; the angle between the extending direction and the arranging direction of each output pad located in the first region and the third region is greater than zero and less than 90°; the extending directions of at least part of the output pads located in the first region, each of the sub-regions and the third region intersect at one point; each output pad located in the first region and the third region has a bottom side close to the intersection point having a length less than a length of a bottom side away from the intersection point.

5. The chip on film according to claim 4, wherein the extending directions of the respective output pads located in the second region are symmetrical with respect to the median line of the second region which is perpendicular to the arranging direction;
the extending directions of the respective output pads located in the first region and the extending directions of the respective output pads located in the third region are symmetrical with respect to the median line of the second region which is perpendicular to the arranging direction.

6. The chip on film according to claim 1, wherein the second region is equally divided into N sub-regions; N is an odd number greater than 1;
the shape of each output pad located in the sub-region which is in the middle of the second region is a rectangle; the extending direction and the arranging direction of each output pad located in the middle sub-region are perpendicular to each other;
the shape of each output pad located in the sub-regions on both sides of the middle sub-region is a parallelogram; the angle between the extending direction and the arranging direction of each output pad located in the sub-regions on both sides of the middle sub-region is greater than zero and less than 90°;
the shape of each output pad located in the first region and the third region is a trapezoid having two bottom sides parallel to the arranging direction; the angle between the extending direction and the arranging direction of each output pad located in the first region and the third region is greater than zero and less than 90°; the extending directions of at least part of the output pads located in the first region, the respective sub-regions and the third region intersect at one point; the length of the bottom side close to the intersection point is less than the length of the bottom side away from the intersection point.

7. The chip on film according to claim 6, wherein the extending directions of the respective output pads located in the sub-regions on both sides of the middle sub-region are symmetrical with respect to the median line of the second region which is perpendicular to the arranging direction;
the extending directions of the respective output pads located in the first region and the extending directions of the respective output pads located in the third region are symmetrical with respect to the median line of the second region which is perpendicular to the arranging direction.

8. The chip on film according to claim 1, wherein the number of the output pads included in each row is 1500-2500;
the angle between the extending direction and the arranging direction of each output pad is in the range of 70° to 80°.

9. The chip on film according to claim 1, wherein in the first region and the third region D, the maximum length spanned by the input pads is gradually increased as they move away from the second region.

10. A flexible display panel, comprising at least one row of input pads positioned in a bonding area of the flexible display panel;
along an arranging direction of the input pads, the area where each row of input pads is located is divided into a first region, a second region and a third region, the second region is located in the middle of the area where the row of input pads is located; the shape of each input pad located in the second region is different from the shape of each input pad located in the first region and the third region, and the maximum length spanned by each input pad located in the second region in the arranging direction is smaller than the minimum value among the maximum lengths spanned by each input pad located in the first region and the third region in the arranging direction.

11. The flexible display panel according to claim 10, wherein the shape of each input pad located in the second region is a rectangle, and the extending direction and the arranging direction of each input pad located in the second region are perpendicular to each other;
the shape of each input pad located in the first region and the third region is a parallelogram; the angle between the extending direction and the arranging direction of each input pad located in the first region and the third region is greater than zero and less than 90°; the extending directions of at least part of the input pads located in the first region, the second region and the third region intersect at one point.

12. The flexible display panel according to claim 11, wherein the extending direction of each input pad located in the first region and the extending direction of each input pad located in the third region are symmetrical with respect to the median line of the second region which is perpendicular to the arranging direction.

13. The flexible display panel according to claim 10, wherein the second region is equally divided into M sub-regions; M is an even number;
the shape of each input pad located in the respective sub-regions is a parallelogram; the angle between the extending direction and the arranging direction of each input pad located in the respective sub-regions is greater than zero and less than 90°;
the shape of each input pad located in the first region and the third region is a trapezoid having two bottom sides parallel to the arranging direction, the angle between the extending direction and the arranging direction of each input pad located in the first region and the third region is greater than zero and less than 90°; the extending directions of at least part of the input pads located in the first region, the respective sub-regions and the third region intersect at one point; the length of the bottom side close to the intersection point is less than the length of the bottom side away from the intersection point.

14. The flexible display panel according to claim 13, wherein the extending directions of the respective input pads located in the second region is symmetrical with respect to the median line of the second region which is perpendicular to the arranging direction;
the extending direction of each input pad located in the first region and the extending direction of each input pad located in the third region are symmetrical with respect to the median line of the second region which is perpendicular to the arranging direction.

15. The flexible display panel according to claim 10, wherein the second region is equally divided into N sub-regions; N is an odd number greater than 1;
the shape of each input pad located in a sub-region which is in the middle of the second region is a rectangle; the extending direction and the arranging direction of each input pad located in the middle sub-region are perpendicular to each other;
the shape of each input pad located in the sub-regions on both sides of the middle sub-region can be set to be a parallelogram; the angle between the extending direction and the arranging direction of each input pad located in the sub-regions on both sides of the middle sub-region is greater than zero and less than 90°;
the shape of each input pad located in the first region and the third region is a trapezoid having two bottom sides parallel to the arranging direction; the angle between the extending direction and the arranging direction of each input pad located in the first region and the third region is greater than zero and less than 90°; the extending directions of at least part of the input pads located in the first region, the respective sub-regions and the third region intersect at one point; the length of the bottom side close to the intersection point is less than the length of the bottom side away from the intersection point.

16. The flexible display panel according to claim 15, wherein the extending directions of the respective input pads located in the sub-regions on both sides of the middle sub-region are symmetrical with respect to the median line of the second region which is perpendicular to the arranging direction;
the extending direction of each input pad located in the first region and the extending direction of each input pad located in the third region are symmetrical with respect to the median line of the second region which is perpendicular to the arranging direction.

17. The flexible display panel according to claim 10, wherein the number of the input pads included in each row is 1500-2500;
the angle between the extending direction and the arranging direction of each input pad is in the range of 70° to 80°.

18. The flexible display panel according to claim 10, wherein in the first region and the third region D, the maximum length spanned by the input pads is gradually increased as they move away from the second region.

19. A display device, comprising the chip on film according to claim 1.

20. The chip on film according to claim 2, wherein in the first region and the third region D, the maximum length spanned by the input pads is gradually increased as they move away from the second region.
